(19) United States
(12) Patent Application Publication
(10) Pub. No.: US 2005/0186054 A1
(43) Pub. Date: Aug. 25, 2005

(54) Materials handling system

(75) Inventor: Yoshitaka Inui, Gamo-gun (JP)

Correspondence Address: REISING, ETHINGTON, BARNES, KISSELLE, P.C., P O BOX 4390, TROY, MI, 48099-4390, US

(73) Assignee: Difuku Co., Ltd.

(21) Appl. No.: 11/112,806

(22) Filed: Apr. 22, 2005

Related U.S. Application Data
(62) Division of application No. 10/071,177, filed on Feb. 8, 2002.

(30) Foreign Application Priority Data
Feb. 21, 2001 (JP) 2001-044386
Feb. 21, 2001 (JP) 2001-044387
Feb. 21, 2001 (JP) 2001-044389

(51) Int. Cl. H05K 13/00; B65G 1/133

(52) U.S. Cl. 414/331.05; 414/935

(57) ABSTRACT

A materials handling system comprises a rotary shelf rotatable around a rotary shelf axis, and a plurality of load receiving sections disposed on a rotary circular path having its center located at the rotary shelf axis. A transfer operating section of a transfer disposed laterally outside the rotary shelf is rotatable around a transfer axis and operates on a transfer circular path tangentially superposed on the rotary circular path, and a fixed shelf is installed on the transfer circular path. The transfer unnecessitates an occupied space for travel, and the whole system including the rotary shelf and fixed shelf can be made compact in size. The transfer having no traveling mechanism allows the transfer operating section to be lowered almost to the floor. With the rotary shelf and fixed shelf, the storage level is allowed to be lowered to further increase the amount of storage.

### RELATED APPLICATIONS

This application is a divisional of U.S. Ser. No. 10/071,177 filed on Feb. 8, 2002.

### FIELD OF THE INVENTION

The present invention relates to a materials handling system employed, for example, in storing or conveying loads in a clean room.

### BACKGROUND OF THE INVENTION

As for this kind of system, an automatic warehouse has been provided in the past as shown, for example, in Japanese Unexamined Patent Publication No. 10-279023.

In this conventional arrangement, a pair of racks having a number of transverse storage positions are disposed in spaced parallel relationship. And, with the spacing used as a travel path, a transfer device is installed between the racks, with rotary racks disposed outwardly of the ends of the travel path. The transfer device comprises a traveling carriage adapted to travel along a lifting and lowering rail laid on one rack, a turntable installed on the traveling carriage, arms, hands, etc. installed on the turntable.

According to such conventional arrangement, delivery of articles is effected between a transfer station, the storage positions of both racks, and the shelf plates of the rotary racks by a combined operation consisting of the lifting and lowering movement of the lifting and lowering rail, the traveling of the traveling carriage, the rotation of the turntable, and the movement of the hands. On this occasion, the rotary racks are suitably rotated. Further, an overhead traveling vehicle supported and guided by the travel rail on the ceiling is installed above the racks, thereby allowing transfer of articles to and from the transfer station disposed on the rack side.

According to the conventional arrangement described above, however, in order to increase the amount of storage, it is necessary either to increase the height of the racks, etc. or to form the racks to be long in size. The idea of forming the racks, etc. to be large in height is limited by factors including the layout of the overhead traveling vehicle and the size of the building and has been impossible to employ easily for a location where it is desired to minimize a clean space, such as a clean room. Further, the idea of forming the racks to be long in size would correspondingly enlarge the occupied space and has been impossible to employ easily for a location, such as a clean room.

Further, as another conventional arrangement, a storage shelf device is shown, for example, in Japanese Unexamined Patent Publication No. 10-98094. The above-mentioned another conventional arrangement comprises a cylindrical shelf disposed in a square box and stackers disposed in the cylindrical shelf. The cylindrical shelf is fixed while the stackers are capable of revolving.

According to the above-mentioned another conventional arrangement described above, however, in order to increase the amount of storage, it is necessary to dispose the storage sections of the cylindrical shelf in vertically and circumferentially closely adjacent relationship. If the storage sections are disposed in vertically closely adjacent relationship, a passageway for maintenance or inspection of the cylindrical shelf or stackers has to be prepared, for which reason the above-mentioned another conventional arrangement has no storage section in the lower region of the cylindrical shelf.

Therefore, in the above-mentioned another conventional arrangement, the amount of storage is small for its scale (height). Thus, the above-mentioned another conventional arrangement has been unable to be easily employed for such a location as a clean room where it is desired to minimize a clean space.

### DISCLOSURE OF THE INVENTION

Accordingly, a first object of the invention is to provide a materials handling system wherein the whole can be made compact in size and yet the amount of storage can be increased.

Further, a second object of the invention is to provide a materials handling system which allows a conveyance means to be laid out in a suitable manner and the whole to be made compact in size.

And a third object of the invention is to provide a materials handling system which allows the whole to be made compact in size and the amount of storage to be increased and which yet allows the maintenance and inspection of the interior to be easily effected.

To achieve the first object described above, a materials handling system according to claim 1 of the invention includes a rotary shelf rotatable around a vertically extending rotary shelf axis and a plurality of load receiving sections disposed on a rotary circular path having its center located at the rotary shelf axis, wherein a transfer means is installed laterally outside the rotary shelf, the transfer means having a transfer operating section which is rotatable around a transfer-means axis parallel with the rotary shelf axis and which is adapted to operate when placed on a transfer circular path tangentially superposed on the rotary circular path, with a fixed shelf installed on the transfer circular path.

According to claim 1 of the invention described above, the rotary shelf is rotated around the rotary shelf axis to position an intended load receiving section in a superposed portion between the rotary circular path and the transfer circular path, thereby allowing the transfer means to effect the taking of loads into and out of the load receiving section. Further, rotating the transfer operating section of the transfer means around the transfer-means axis allows the transfer means to effect the taking of loads into and out of the fixed shelf.

Thus, since the transfer means causes the transfer operating section to rotate only, without causing it to travel, an occupied space for travel or the like is unnecessary, allowing the whole including the rotary shelf and fixed shelf to be made compact in size. Furthermore, the use of the rotary shelf and fixed shelf allows the amount of storage to be increased and the transfer means, which has no traveling mechanism, to lower the transfer operating section almost to the floor, thereby allowing the storage levels of the rotary shelf and fixed shelf to be correspondingly lowered, thus further increasing the amount of storage. Therefore, the invention can be easily and suitably employed for a location where it is desired to minimize a clean space, such as a clean room.

In a first preferred embodiment with the materials handling system of claim 1 of the invention, the rotary shelf, transfer means and fixed shelf are associated with one rotary circular path and one transfer circular path.

According to this first embodiment, the materials handling system comprising the rotary shelf, transfer means and fixed shelf can be compactly constructed.

In a second preferred embodiment with the materials handling system of claim 1 of the invention, the fixed shelf is installed in each of a plurality of places on the transfer circular path.

According to this second embodiment, the amount of storage can be increased by a group of fixed shelves.

In a third preferred embodiment with the materials handling system of claim 1 of the invention, the rotary shelf is provided with groups of load receiving sections in a plurality of vertically spaced steps, the fixed shelf is provided with load support sections in a plurality of vertically spaced steps, and the transfer means is adapted to operate correspondingly to a plurality of vertically spaced steps in the rotary shelf and the fixed shelf.

According to this third embodiment, the use of the rotary shelf and the fixed shelf can increase the amount of storage by utilizing the height to the greatest extent, and this embodiment can be easily employed for a clean room or the like.

In a fourth preferred embodiment with the materials handling system of claim 1 of the invention, the rotary shelf is rotatable forwardly and backwardly by an angle up to a maximum of 180 degrees.

According to this fourth embodiment, the rotation of the rotary shelf can be effected forwardly or backwardly by an angle up to a maximum of 180 degrees along a path which corresponds to the shorter distance of rotation of an intended load receiving section with respect to a superposed position; thus, quick and efficient rotation can be effected.

In a fifth preferred embodiment with the materials handling system of claim 1 of the invention, it is arranged that when the transfer means is working with respect to the fixed shelf, the rotary shelf is prepared in advance.

According to this fifth embodiment, overall operating efficiency can be improved by rotating the rotary shelf for preparation in advance when the transfer means is working with respect to the fixed shelf.

In a sixth preferred embodiment with the materials handling system of claim 1 of the invention, the rotary shelf, transfer means and fixed shelf are disposed in a clean atmosphere.

According to this sixth embodiment, in the rotary shelf and fixed shelf, storage of loads can be effected in a sufficiently clean atmosphere.

To achieve the second object of the invention described above, a materials handling system according to claim 8 of the invention includes a rotary shelf rotatable around a vertically extending rotary shelf axis and a plurality of load receiving sections disposed on a rotary circular path having its center located at the rotary shelf axis, wherein a rectangular box-like surrounding wall body surrounds the rotary shelf, at least one corner of the surrounding wall body being formed as a cut portion over a vertically extending set range, and a conveyance means is installed which passes outside the cut portion.

According to claim 8 of the invention described above, conveyance by the conveyance means can be quickly and efficiently effected in the shortest distance sufficiently close to the surrounding wall body by utilizing a conveyance path or the like positioned outside the cut portion. Further, since the conveyance means can be disposed sufficiently close to the surrounding wall body, the occupied space extending from the surrounding wall body to the conveyance path can be made narrow; thus, the layout of the conveyance means can be easily and suitably made and the whole can be made compact in size.

In a first preferred embodiment with the materials handling system of claim 8 of the invention, the surrounding wall body is formed with a load passage portion for delivery of loads to and from the conveyance means.

According to this first embodiment, delivery of loads between an equipment within the surrounding wall body and the conveyance means can be effected through the load passage portion.

In a second preferred embodiment with the materials handling system of claim 8 of the invention, installed within the surrounding wall body in addition to the rotary shelf are the fixed shelf and the transfer means adapted to operate on the rotary shelf and the fixed shelf.

According to this second embodiment, storage of loads can be effected within the surrounding wall body by the rotary shelf and the fixed shelf, and loads can be taken into and out of the rotary shelf and the fixed shelf by the transfer means.

In a third preferred embodiment with the materials handling system of claim 8 of the invention, installed within the surrounding wall body in addition to the rotary shelf are the fixed shelf and the transfer means, the transfer means being disposed laterally outside the rotary shelf. The transfer operating section of the transfer means is rotatable around the transfer axis parallel with the rotary shelf axis and is adapted to operate when placed on a transfer circular path tangentially superposed on the rotary circular path, with the fixed shelf being disposed on the transfer circular path.

According to this third embodiment, rotating the rotary shelf around the rotary shelf axis to position an intended load receiving section in the superposed portion between the rotary circular path and the transfer circular path allows the transfer means to effect the taking of loads into and out of this load receiving section. Further, rotating the transfer operating section of the transfer means around the transfer means axis allows the transfer means to effect the taking of loads into and out of the fixed shelf.

Thus, since the transfer means causes the transfer operating section only to rotate, without causing it to travel, an occupied space for travel is unnecessary, allowing the whole including the rotary shelf and the fixed shelf to be made compact in size. Moreover, the use of the rotary shelf and the fixed shelf can increase the amount of storage, and the transfer means, which has no traveling mechanism, allows the transfer operating section to be lowered almost to the floor, thereby allowing the storage levels of the rotary shelf and the fixed shelf to be correspondingly lowered and the amount of storage to be increased. Therefore, the invention can be easily and suitably employed for a location where it is desired to minimize a clean space, such as a clean room.

In a fourth preferred embodiment with the materials handling system of claim 8 of the invention, the inside of the surrounding wall body is in a clean atmosphere.

According to this fourth embodiment, the rotary shelf can be installed in a sufficiently clean atmosphere.

In a fifth preferred embodiment with the materials handling system of claim 8 of the invention, the surrounding wall body is disposed in a clean room.

According to this fifth embodiment, the surrounding wall body within which the rotary shelf is disposed can be installed in a sufficiently clean atmosphere.

To achieve the third object of the invention described above, a materials handling system according to claim 14 of the invention includes a rotary shelf rotatable around a vertically extending rotary shelf axis and a plurality of load receiving sections disposed on a rotary circular path having its center located at the rotary shelf axis, wherein a surrounding wall body surrounds the rotary shelf, and disposed within the surrounding wall body in addition to the rotary shelf are a fixed shelf and a transfer means adapted to operate on the fixed shelf, part of the surrounding wall body being formed as an opening/closing door, the fixed shelf being disposed within the opening/closing door, the fixed shelf being movable through an opening left after the opening/closing door has been opened.

According to claim 14 of the invention described above, the fixed shelf can store loads sufficiently down to the bottom, the whole can be made compact in size, and the amount of storage can be increased; thus, the invention can be easily and suitably applied to a location where it is desired to minimize a clean space, such as a clean room. And, after the opening/closing door has been moved to open so as to uncover the opening, the fixed shelf can be swung (moved) into the outside of the surrounding wall body through the opening; thus, a passage can be formed inside the opening at a portion from which the fixed shelf moved.

This allows the operator to move into and out of the surrounding wall body from the opened region through the passage; thus, maintenance, inspection and the like of the transfer means and others disposed within the surrounding wall body can be easily and reliably effected. And, maintenance, inspection and the like of the fixed shelf, which has been swung, may be effected outside the surrounding wall body. After the intended maintenance and inspection have been made, firstly the fixed shelf is swung (moved) into the surrounding wall body to position it in a predetermined place and then the opening/closing door is moved for closing.

In a first preferred embodiment with the materials handling system of claim 14 of the invention, the transfer means is adapted to operate on the fixed shelf and the rotary shelf.

According to this first embodiment, the taking of loads into and out of the fixed shelf and the rotary shelf can be effected by the transfer means. And, swinging (moving) the fixed shelf along with the opening/closing door into the outside of the surrounding wall body allows easy and reliable maintenance, inspection and the like of the rotary shelf.

In a second preferred embodiment with the materials handling system of claim 14 of the invention, a transfer means is installed laterally outside the rotary shelf, the transfer means having a transfer operating section which is rotatable around a transfer axis parallel with the rotary shelf axis and which is adapted to operate when placed on a transfer circular path tangentially superposed on the rotary circular path, and disposed on the transfer circular path is a fixed shelf which is movable through an opening left after the opening/closing door has been moved for opening.

According to this second embodiment, rotating the rotary shelf around the rotary shelf axis to position the intended load receiving section in the superposed portion between the rotary circular path and the transfer circular path allows the transfer means to effect the taking of loads into and out of this load receiving section. Further, rotating the transfer operating section of the transfer means around the transfer means axis allows the transfer means to effect the taking of loads into and out of the fixed shelf.

Thus, since the transfer means causes the transfer operating section only to rotate, without causing it to travel, an occupied space for travel is unnecessary, allowing the whole including the rotary shelf and the fixed shelf to be made compact in size. Moreover, the use of the rotary shelf and the fixed shelf can increase the amount of storage, and the transfer means, which has no traveling mechanism, allows the transfer operating section to be lowered almost to the floor, thereby allowing the storage levels of the rotary shelf and the fixed shelf to be correspondingly lowered, so that the amount of storage can be further increased.

### BRIEF DESCRIPTION OF THE DRAWINGS

FIG. 1 is an external perspective view of a materials handling system, showing a first embodiment of the invention;

FIG. 2 is a plan view, in cross section, of the materials handling system;

FIG. 3 is a side view, in longitudinal section, of the materials handling system;

FIG. 4 is a fragmentary side view of a lower portion of a rotary shelf in the materials handling system;

FIG. 5 is a fragmentary side view of an upper portion of the rotary shelf in the materials handling system;

FIG. 6 is a fragmentary side view of a lower portion of a transfer means in the materials handling system;

FIG. 7 is a fragmentary side view of an upper portion of the transfer means in the materials handling system;

FIG. 8 is a fragmentary plan view of the transfer means in the materials handling system;

FIG. 9 is a side view of a fixed shelf in the materials handling system;

FIG. 10 is a plan view of the fixed shelf in the materials handling system;

FIG. 11 shows second through fifth embodiments of the invention, wherein (a) is a schematic plan view showing the second embodiment, (b) is a schematic plan view showing the third embodiment, (c) is a schematic plan view showing the fourth embodiment, and (d) is a schematic plan view showing the fifth embodiment;

FIG. 12 is a fragmentary side view of a materials handling system, showing a sixth embodiment of the invention;

FIG. 13 is an external perspective view of a materials handling system, showing a seventh embodiment of the invention;

FIG. 14 is a side view of a fixed shelf and a transfer means in the materials handling system;

FIG. 15 is a plan view, in cross section, of the materials handling system; and

FIG. 16 is a plan view, in cross section, of a portion of the fixed shelf in the materials handling system.

### DETAILED DESCRIPTION OF THE PREFERRED EMBODIMENTS

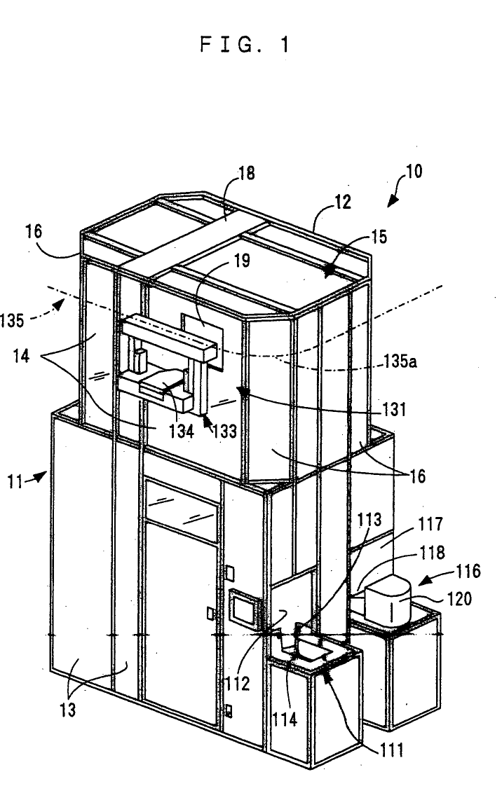

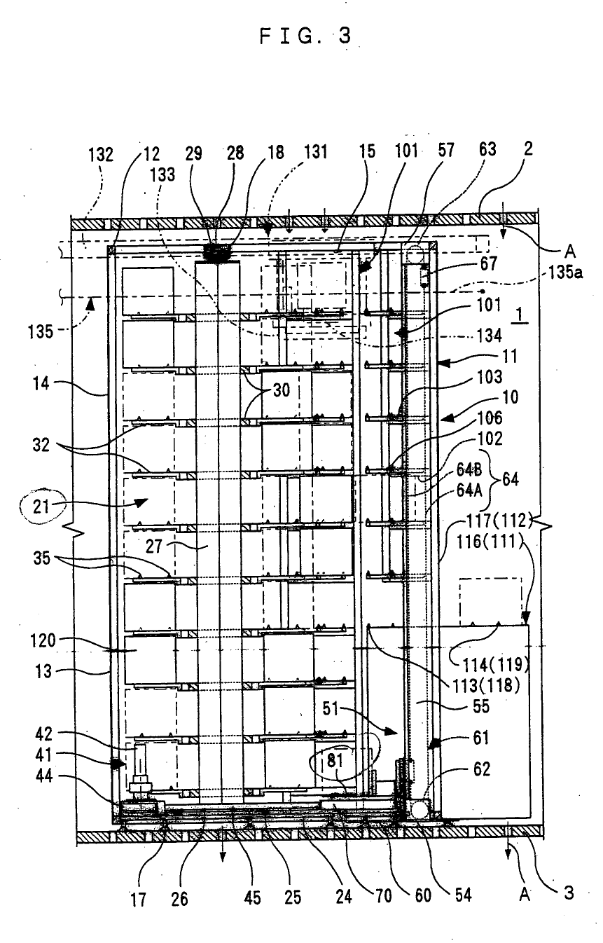

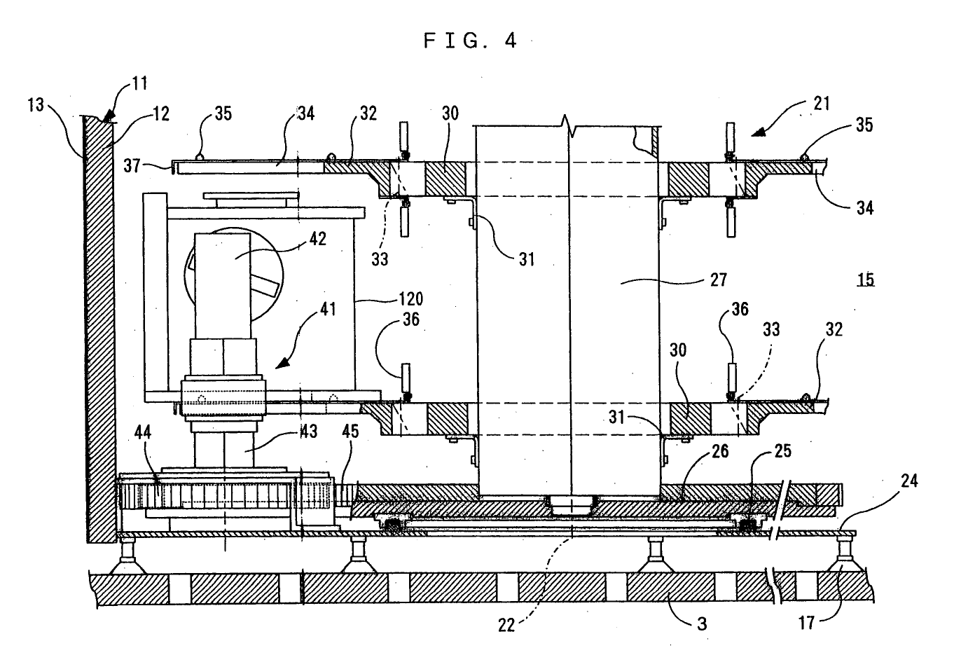

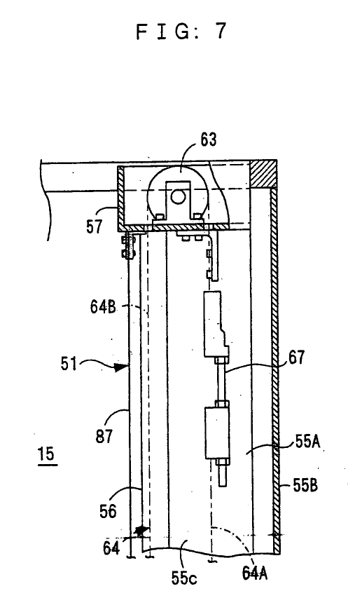

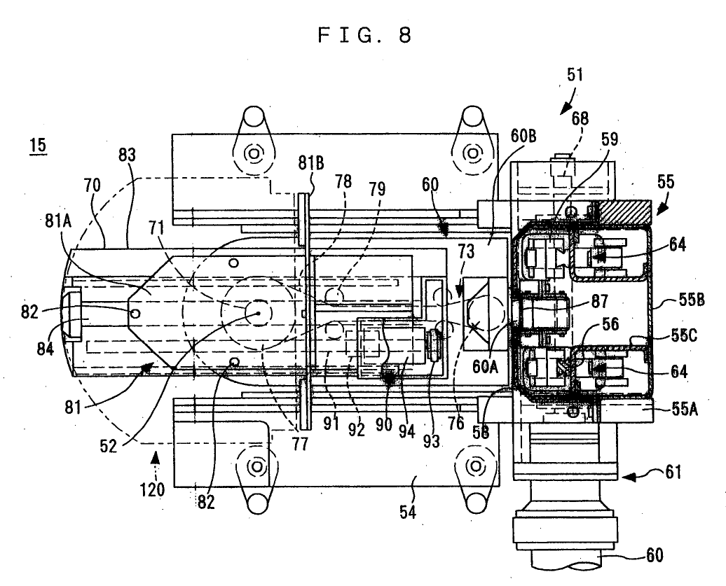

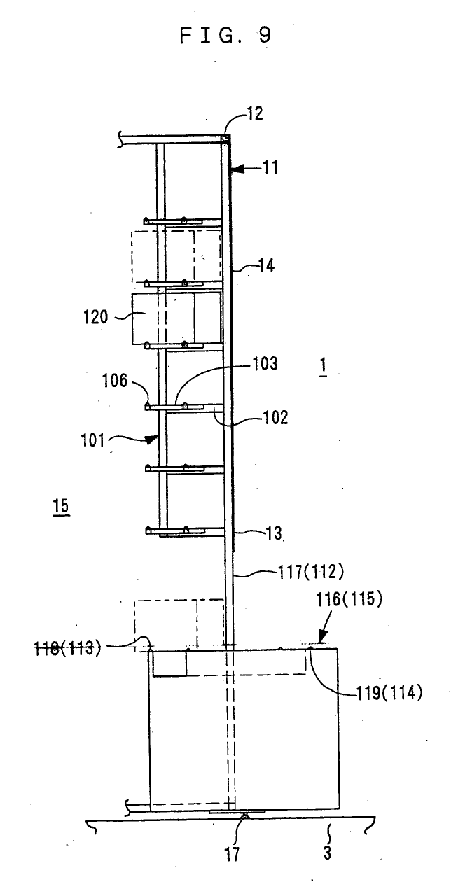

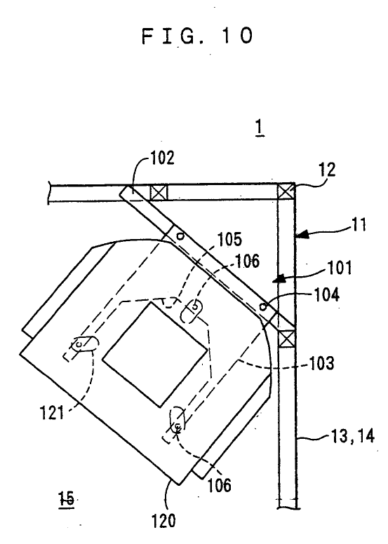

A first embodiment of the invention will now be described with reference to FIGS. 1-10.

In FIGS. 1-3, a clean room 1 employs, for example, a downflow system in which clean air A is blown from a ceiling 2 and discharged to the lower side of a floor 3. And a load storage facility 10 is installed in the clean room 1. The load storage facility 10 comprises a rectangular box-like surrounding wall body 11, and a rotary shelf 21, a transfer means 51, a fixed shelf 101, etc., which are disposed within the surrounding wall body 11.

The surrounding wall body 11 comprises a frame body 12, lower outer plates 13 fixed to the lower half of the frame body 12 on the outer side thereof, outer upper plates 14 fixed to the upper half of the frame body 12 on the outer side thereof, etc. On this occasion, transparent plates of resin or the like are used for at least either of the lower and upper outer plates 13 and 14, mainly the upper outer plates 14; thus, the situation of a load storage chamber (load storage space) 15 within the surrounding wall body 11 can be grasped from outside. Further, with the overall height of the upper outer plate 14, for example, defined as a set region in at least one corner of the surrounding wall body 11, the four corners are formed as cut portions 16.

The surrounding wall body 11 consisting of the above arrangement is opened at its upper and lower ends, so that clean air A is blown from the ceiling 2 to pass through the inside of the surrounding wall body 11, whereby the load storage chamber 15 within the surrounding wall body 11 is in a clean atmosphere. In addition, the surrounding wall body 11 is disposed on the floor 3 through leg bodies 17 disposed under the frame body 12.

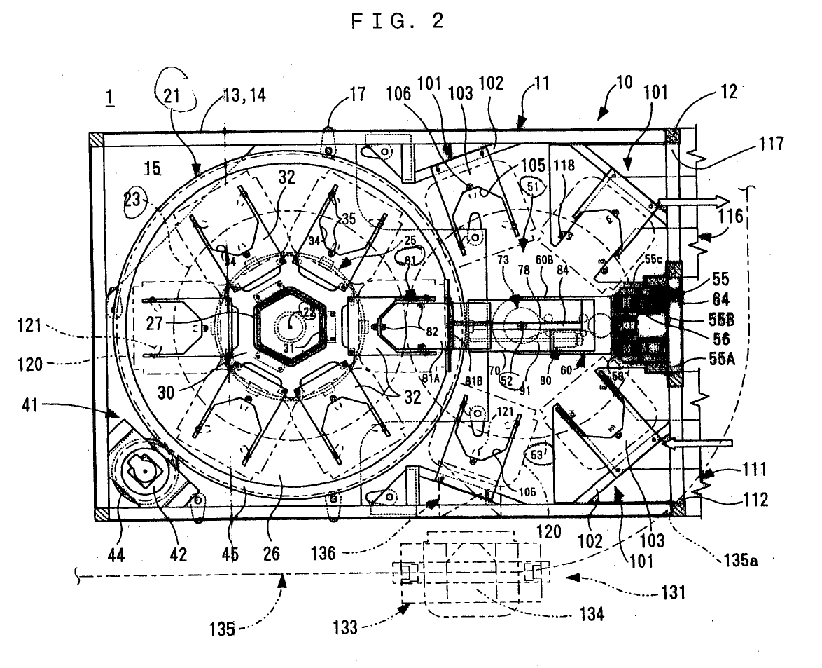

In FIGS. 2-5, the rotary shelf 21 is disposed closer to one side within the load storage chamber 15. This rotary shelf 21 is rotatable around a vertical rotary shelf axis 22 and has a plurality of load receiving sections 32 disposed on a rotary circular path 23 having its center located at the rotary shelf axis 22.

That is, a base plate 24 is disposed on the floor 3, and disposed on this base plate 24 is a disk-like rotary body 26 through a circular LM guide means 25 having its center located at the rotary shelf axis 22. A hexagonal prismatic vertical shaft body 27 is erected on the central portion of the rotary body 26 so that it is positioned on the rotary shelf axis 22. A closure plate 27A is installed on the upper end of the vertical shaft body 27. And a vertical pin 28 erected on the central portion of the closure plate 27A is freely rotatably supported by a support plate 18, which is installed in the upper region of the surrounding wall body 11, through a bearing device 29.

Fitted on the vertical shaft body 27 in a plurality of vertically spaced places are hexagonal annular plates 30, which are connected to the vertical shaft body 27 through a plurality of fixtures 31 or the like. The load receiving section 32 is disposed in each of six places (a plurality of places) on the circumference of each annular plate 30. These load receiving sections 32 are in the form of plate frames, with the base ends connected to the annular plates 30 through connectors 33, whereby they are supported on the annular plate 30 side in a cantilever manner while projecting transversely outward.

Each load receiving section 32 is formed with a recess 34 which is opened vertically and at the free end outer side, and a positioning pin 35 is erected in each of three places (a single place or a plurality of places) around the recess 34. Further, a reflecting mirror 36 constituting part of a load presence detecting means is installed in the base end portion of the load receiving section 32, while are reflecting tape 37 constituting part of a level detecting means is installed in the free end portion.

A rotary shelf driving means 41 for rotating the rotary shelf 21 is installed. That is, a rotary unit 42 is disposed at a corner of the base plate 24, and a drive shaft 43 extending downward from the rotary unit 42 is provided with a drive gear 44. And the peripheral edge of the rotary body 26 is provided with a ring gear 45, constantly meshing with the drive gear 44. The rotary unit 42 consists of a motor, a speed reducer, etc., and is adapted to drive the drive shaft 43 forwardly and backwardly.

Therefore, forwardly and backwardly driving the drive shaft 43 by the rotating drive unit 42 of the rotary shelf driving means 41 allows the rotary shelf 21 to rotate forwardly and backwardly around the rotary shelf axis 22 through the drive gear 44, ring gear 45, etc. On this occasion, the rotary shelf 21 is adapted to rotate by an angle up to a maximum of 180 degrees. The 22-45, etc., constitute an example of rotary shelf 21.

In FIGS. 2, 3, and 6-8, the transfer means 51 is disposed in the load storage chamber 15 and closer to the other side thereof. The transfer operating section 81 of this transfer means 51 is rotatable around a transfer axis 52 parallel with the rotary shelf axis 22 and is adapted to operate when placed on a transfer circular path 53 tangentially superposed on the rotary circular path 23.

That is, a base frame 54 is installed on the floor 3, and a post body 55 is erected on the base frame 54, the post body 55 having guide rails 56 disposed on the front surface thereof. The post body 55 comprises a pair of side members 55A, a rear member 55B disposed between the inner surfaces of these side members 55A, and front members 55C disposed on the front surface of the rear member 55B, these front members 55C having the guide rails 56 respectively disposed on the front surfaces thereof. And an upper frame 57 is disposed on the upper end of the post body 55, and the front members 55C are each provided with a cover body 58.

The guide rail 56 is provided with a lifting and lowering section 60 guided for lifting and lowering movement (LM guide) through a guided body 59, the lifting and lowering section 60 having a lifting and lowering drive means 61 interlocked thereto. That is, the lifting and lowering section 60 is formed in L-shape as viewed laterally by a longitudinal member 60A connected to the guided body 59 and a transverse member 60B extending forwardly from the lower end of the longitudinal member 60A.

The lifting and lowering drive means 61 comprises a pair of drive wheel bodies 62 disposed in the base frame 54, a pair of driven wheel bodies 63 disposed in the upper frame 57, a pair of rotary bodies 64 (such as timing belts) entrained between the two wheel bodies 62 and 63, a pair of guide wheel bodies 65 disposed adjacent the drive wheel bodies 62, a rotary section 66 interlocked to the drive wheel bodies 62, etc.

On this occasion, each rotary body 64 comprises a lower rotary section 64A entrained around the drive wheel body 62, and an upper rotary section 64B entrained around the driven wheel body 63. And, the respective free ends positioned on the front surface of the post body 55 are connected to the guided body 59, while the respective free ends positioned on the rear surface are connected through a tension adjuster 67. The rotary section 66 is composed of a reversible motor, a speed reducer, etc., and has a drive shaft 68 having a pair of drive wheel bodies 62 attached thereto.

A rotary body 70 rotatable around the transfer axis 52 is installed on the transverse member 60B of the lifting and lowering section 60. On this occasion, a vertical shaft 71 extending downwardly from the middle portion of the rotary body 70 is rotatably supported by a bearing 72 on the transverse member 60B side. And a rotary means 73 is interlocked to the vertical shaft 71.

That is, the rotary means 73 is composed of a rotary section 74 extending from the vertical member 60A to the transverse member 60B, a drive wheel body 76 attached to a drive shaft 75 downwardly extending therefrom, a driven wheel body 77 attached to the vertical shaft 71, an endless rotary body (such as timing belt) 78 entrained between the two wheel bodies 76 and 77, a plurality of guide wheel bodies 79 disposed in the transverse member 60B, etc. The rotary section 74 is composed of a reversible motor, a speed reducer, etc.

The transfer operating section 81 is of the fork type and adapted to advance and retract in the front/rear direction (transverse direction) with respect to the rotary body 70; thus, it is rotatable around the transfer axis 52. That is, the transfer operating section 81 is composed of a front/rear support plate 81A, a deviation control plate 81B erected on the intermediate portion of the support plate 81A, etc. And, a plurality of positioning pins 82 are erected on the support plate 81A forwardly of the deviation control plate 81B.

A pair of rail members 83 are disposed on the rotary body 70 to extend in the front/rear direction, and a front/rear guide body 84 is disposed between these rails 83 and in the left/right middle portion. And, disposed at the rear end and in the lower surface of the support plate 81A is a guided body 85 fitted on the guide body 84 and constituting an LM guide.

An advance/retraction drive means 90 is installed which is adapted to advance and retract the transfer operating section 81 in the front/rear direction. That is, the advance/retraction drive means 90 is composed of a screw shaft 91 extending along the guide body 84, a nut body 92 disposed on the lower surface side of the transfer operating section 81 and screwed on the screw shaft 91, a rotary section 94 mounted on the rotary body 70 and interlocked to the screw shaft 91 through a belt interlock mechanism 93, etc. The rotary section 94 is composed of a reversible motor, a speed reducer, etc.

In addition, the support plate 81A of the transfer operating section 81 is adapted for lifting and lowering movement with respect to the recess 34 in the load receiving section 32. And the post body 55 is provided with a dust-proof belt 87 which allows the lifting and lowering of the guided body 59 and which is capable of closing the clearance between the two cover bodies 58, while the rotary body 70 is provided with a dust-proof belt 88 which allows back and forth movement of the transfer operating section 81 and which is capable of closing the region above the guide body 84.

The 52-94, etc. constitute an example of transfer means 51. And the transfer operating section 81 of the transfer means 51 is rotatable around the transfer axis 52 parallel with the rotary shelf axis 22 and is adapted to operate when placed on the transfer circular path 53 tangentially superposed on the rotary circular path 23.

In FIGS. 2, 3, 9 and 10, the fixed shelf 101 is provided in each of four places (a single place or a plurality of places) closer to the other side in the load storage chamber 15 and on the transfer circular path 53. That is, within the surrounding wall body 11, transverse flat bars 102 are connected in a plurality of vertically spaced places on the frame body 12 side, and each flat bar 102 is provided with a load support section 103. These load support sections 103 are in the form of plate frames whose base ends are connected to the flat bars 102 through connectors 104; thus, they are supported in a cantilever manner by the flat bars 102 while projecting transversely forward.

And the load support section 103 is formed with a recess 105 which is opened vertically and at the free end (outer side), and a positioning pin 106 is erected in each of three places (a single place or a plurality of places) around the recess 105. In addition, the support plate 81A of the transfer operating section 81 is adapted to be capable of lifting and lowering movement with respect to the recess 105. The 102-106, etc. constitute an example of fixed shelf 101.

In FIGS. 1-3, and 9, the fixed shelf 101 is provided with a storage load handling section 111 and a retrieval load handling section 116. That is, the lower outer plate 13 on the other side in the surrounding wall body 11 is formed with a storage through-portion 112 and a retrieval through-portion 117, and the load handling sections 111 and 116 extend through these through-portions 112 and 117 to lie across the surrounding wall body 11.

And the inner end portions of the load handling sections 111 and 116 are positioned to project into the fixed shelf 101 disposed closest to the other side. On this occasion, the inner end portions of the load handling sections 111 and 116 are bent as seen from above and then project into the fixed shelf 101 immediately from behind, which projection results in the fixed shelf 101 having its load support sections 103, etc. removed in a predetermined number of vertically spaced steps.

The inner end portions of the load handling sections 111 and 116 are formed in the same manner as in the load support sections 103 to allow the transfer means 51 to operate, and similar inner positioning pins 113 and 118 are installed. Further, the outer end portions of the load handling sections 111 and 116 are also provided with similar outer positioning pins 114 and 119. In addition, disposed in the load handling sections 111 and 116 are conveyance means (not shown) such as belt conveyors capable of lifting and lowering movement.

As described above, the rotary shelf 21, transfer means 51 and fixed shelf 101 are disposed within the surrounding wall body 11 and are associated with one rotary circular path 23 and one transfer circular path 53. And the fixed shelf 101 is provided in each of four pieces (a plurality of places) on the transfer circular path 53.

Further, the rotary shelf 21 is provided with a group of load receiving sections 32 in a plurality of vertically spaced steps, while the fixed shelf 101 is provided with load support section 103 in a plurality of vertically spaced steps. Further, the transfer means 51 is adapted to operate correspondingly to the vertically spaced steps in the rotary shelf 21 and fixed shelf 101. And the rotary shelf 21, transfer means 51 and fixed shelf 101 are disposed within the surrounding wall body 11 within which a clean atmosphere is maintained. In addition, the lower surface of a cassette (an example of load) 120 is formed with fitting portions 121 in recessed elongated form allowing the fitting of groups of the positioning pin 35, 82, 106, 113, 114, 118 and 119.

In FIGS. 1-3, a conveyance means 131 extends outside the cut portion 16 in the surrounding wall body 11. That is, the conveyance means 131 is composed of a rail device 132 on the ceiling, a suspension travel type movable body 133 capable of automatic travel as supported and guided by the rail device 132, a load holding section 134 disposed on the lower side of the movable body 133, etc. And a conveyance path 135 which is a travel path for the movable body 133 is formed so that a curved path portion 135a is positioned outside the cut portion 16.

The surrounding wall body 11 is formed with a load passage portion 19 for delivery of the cassette 120 to and from the conveyance means 131. That is, on the outer side of the fixed shelf 101 on the side closer to the rotary shelf 21, the upper outer plate 14 is formed with the load passage portion 19 in the form of an opening. And, opposed to the load passage portion 19 and in the fixed shelf 101, a delivery means 136 is provided which is capable of delivery of the cassette 120 to and from the load holding section 134 of the movable body 133.

This delivery means 136 is, for example, of the fork type, the transfer means 51 being adapted to be capable of delivery of the cassette 120 with respect to the delivery means 136.

The operation of the first embodiment described above will now be described.

In the clean room 1, clean air A is blown from the ceiling 2 and discharged to the lower side of the floor 3, whereby a clean atmosphere is maintained by the downflow system. Further, part of the clean air A from the ceiling 2 is caused to flow down into the surrounding wall body 11 of the load storage facility 10 installed in the clean room 1, whereby a clean atmosphere is also preserved within the surrounding wall body 11.

To store the cassette 120 in the load storage facility 10 in such clean room 1, first the cassette 120 to be stored is placed on the outer end portion of the storage load handling section 111 and its fitting portions 121 are fitted on the outer positioning pins 114. On this occasion, the cassette 120 is fed by manual operation or by a storing device. The cassette 120 placed on the outer end portion of the storage load handling section 111 is conveyed by the conveyance means and positioned on the inner end portion of the storage load handling section 111 through the storage through-section 112, and its fitting portions 121 are fitted on the inner positioning pins 113.

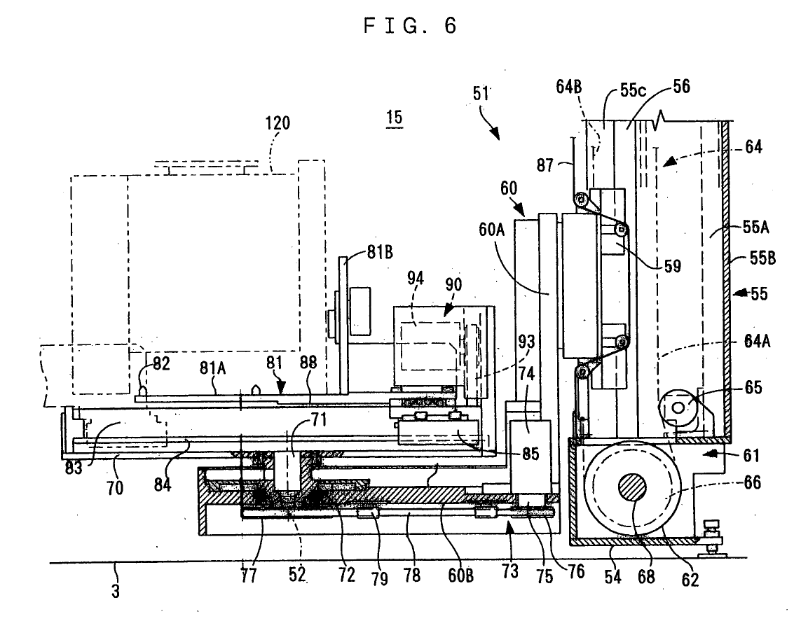

Subsequently, the cassette 120 positioned on the inner end portion of the storage load handling section 111 is received by the transfer means 51. On this occasion, as shown in solid lines in FIG. 6, with the empty transfer operating section 81 retracted into the rotary body 70, rotation and lifting/lowering of the transfer operating section 81 are effected simultaneously or one of them is effected first and then the other.

That is, the rotation of the transfer operating section 81 causes the rotary section 74 in the rotary means 73 to be driven forwardly and backwardly, rotating the drive wheel body 76 forwardly and backwardly through the drive shaft 75. This allows the vertical shaft 71 to rotate forwardly and backwardly through the endless rotary body 78 and driven wheel body 77; thus, the transfer operating section 81 can be rotated forwardly and backwardly around the transfer axis 52 through the rotary body 70.

Further, the lifting and lowering of the transfer operating section 81 causes the rotary section 66 in the lifting and lowering drive means 61 to drive forwardly and backwardly, thereby rotating the drive wheel body 62 forwardly and backwardly through the drive shaft 68. This allows the rotary body 64 to rotate forwardly and backwardly; thus, the transfer operating section 81 can be lifted and lowered through the guided body 59 and the lifting and lowering section 60.

Rotating and lifting and lowering the transfer operating section 81 in this manner allows the transfer operating section 81 to be opposed to the inner end portion of the storage load handling section 111 at a somewhat lower level.

Subsequently, the transfer operating section 81 is caused to project. That is, the rotary section 94 in the advance/retraction drive section 90 is driven to rotate the screw shaft 91 through the belt interlocking mechanism 93. This causes threaded movement of the nut body 92, projecting the transfer operating section 81, on which occasion the transfer operating section 81 guides the guided body 85 by the guide body 84, whereby, as shown in phantom lines in FIG. 6, it can project linearly. This projecting movement allows the transfer operating section 81 to be positioned under the cassette 120 placed on the inner end portion of the storage load handling section 111.

In this state, the operation of the lifting and lowering drive means 61 described above somewhat lifts the transfer operating section 81 through the lifting and lowering section 60, etc. Thereupon, the transfer operating section 81 is lifted through the recess in the inner end portion of the storage load handling section 111; thus, the cassette 120 placed on the inner end portion of the storage load handling section 111 can be lifted, on which occasion the positioning pins 82 are fitted in the fitting portions 121. And the advance/retraction drive means 90 is actuatated in reverse order to what is described above so as to retract the transfer operating section 81, whereby the cassette 120 can be positioned above the rotary body 70.

Subsequently, in the same manner as described above, the transfer operating section 81 is rotated and it is lifted and/or lowered as the occasion demands, whereby the cassette 120 can be opposed to the intended load support section 103 of the intended fixed shelf 101. At this time, the transfer operating section 81 is positioned somewhat above the level of the load support section 103.

And the transfer operating section 81 is caused to project in the same manner as described above, whereby the cassette 120 can be positioned above the load support section 103. Subsequently, the transfer operating section 81 is somewhat lowered, whereby the cassette 120 can be placed on the load support section 103. On this occasion, the fitting portions 121 are fitted on the positioning pins 106, and then the transfer operating section 81 is retracted. This allows the cassette 120, which is positioned on the inner end portion of the storage load handling section 111, to be stored in the fixed shelf 101. That is, the storing operation of storing the cassette 120, which is fed to the storage load handling section 111, in the load support section 103 of the fixed shelf 101 disposed on the transfer circular path 53 is completed.

Further, the cassette 120 positioned on the inner end portion of the storage load handling section 111 can be stored also in the rotary shelf 21. That is, during the operation in which the cassette 120 positioned on the inner end portion of the storage load handling section 111 is received by the transfer means 51 as described above, the rotary shelf 21 can be rotated in advance for preparation.

This rotation of the rotary shelf 21 causes the rotary section 42 in the rotary shelf drive means 41 to be driven forwardly and backwardly, rotating the drive gear 44 forwardly and backwardly through the drive shaft 43. This allows the ring gear 45 to rotate forwardly and backwardly; thus, the group of load support sections 32 can be rotated around the rotary shelf axis 22 through the vertical shaft body 27, etc. On this occasion, the group of load receiving sections 32 is rotation-moved on the rotary circular path 23 and the rotation stops when the intended load receiving section 32 reaches a position which is tangentially superposed on the transfer circular path 53.

In addition, the rotation of the rotary shelf 21 can be effected forwardly or backwardly by an angle up to a maximum of 180 degrees along a path which corresponds to the shorter distance of rotation of the intended load receiving section 32 with respect to the superposed position; thus, quick and efficient rotation can be effected. Further, during receiving operation by the transfer means 51, the rotary shelf 21 is rotated in advance for preparation, thereby improving the overall operating efficiency. In addition, when the intended load receiving section 32 is in the superposed position from the beginning, rotation of the rotary shelf 21 will not be effected.

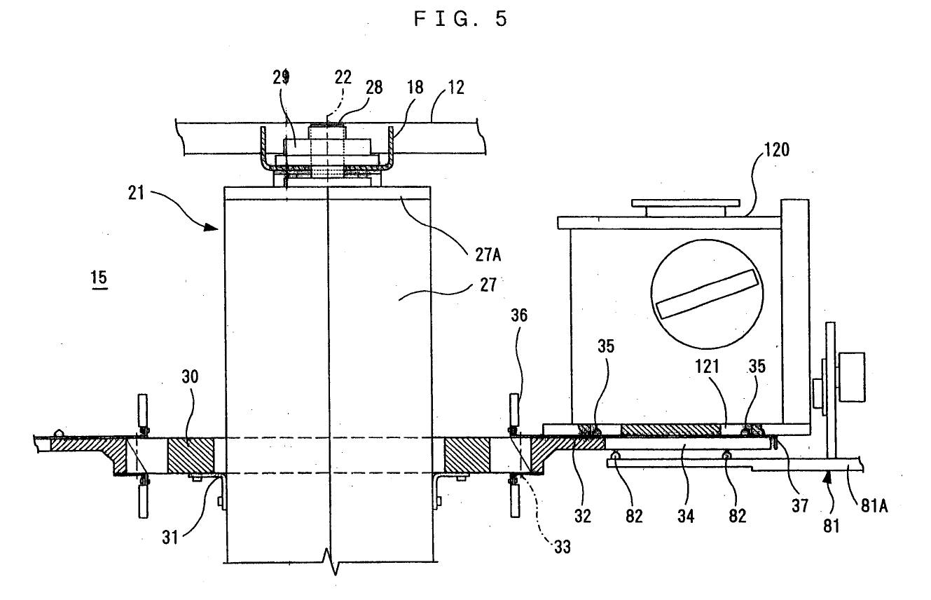

Thus, after the intended load receiving section 32 is stopped at the superposed position, the transfer means 51 is operated in the same manner as described above, whereby the cassette 120 supported on the transfer operating section 81 can be placed on the load receiving section 32, as shown in FIGS. 2 and 5. On this occasion, the fitting portions 121 are fitted on the positioning pins 35. This allows the cassette 120, which is positioned on the inner end portion of the storage load handling section 111, to be placed on the intended load receiving section 32 of the rotary shelf 21; thus, the operation of storing the cassette 120, which is fed to the storage load handling section 111, in the rotary shelf 21 is completed.

In addition, the cassette 120 stored in the fixed shelf 101 can be likewise transferred to and stored in the rotary shelf 21 by the operation of the transfer means 51 and the rotation of the rotary shelf 21. On this occasion, during the operation in which the cassette 120 in the fixed shelf 101 is received by the transfer means 51, the rotary shelf 21 can be rotated in advance for preparation, whereby the overall operating efficiency can be increased. On this occasion, when the intended load receiving section 32 is in the superposed position from the beginning, rotation of the rotary shelf 21 will not be effected.

Retrieval of the cassette 120 can be effected by operating the transfer means 51 in reverse order to what is described above. That is, the cassette 120 placed on the intended load receiving section 32 of the rotary shelf 21 can be positioned on the inner end portion of the retrieval load handling section 116, while the cassette 120 placed on the intended load support section 103 of the intended fixed shelf 101 can be positioned on the inner end portion of the retrieval load handling section 116. And, the cassette 120 placed on the inner end portion of the retrieval load handling section 116 can be conveyed by the conveyance means and positioned on the outer end portion of the retrieval load handling section 116 through the retrieval through-portion 117, whereupon the retrieval operation is completed.

In addition, the cassette 120 stored in the rotary shelf 21 can also be likewise transferred (retrieved) to the fixed shelf 101 for storage therein by the operation of the transfer means 51 and the rotation of the rotary shelf 21.

In the individual operations described above, the fitting portions 121 of the cassette 120 fit on the positioning pins 35, 82, 106, 113, 114, 118 and 119, thereby preventing the cassette 120 from colliding with another cassette 120 or from deviating or falling off owing to centrifugal force or the like produced during rotation.

Since the transfer means 51 only rotates around the transfer axis 52 of the transfer operating section 81 without traveling, as described above, the occupied space for travel or the like becomes unnecessary; thus, the whole including the rotary shelf 21 and fixed shelf 101 can be made compact in size.

Furthermore, the use of the rotary shelf 21 and the fixed shelf 101 allows the amount of storage to be increased and allows the transfer means 51, having no traveling mechanism, to lower the transfer operating section 81 almost to the floor; thus, in conjunction therewith, the storage level to be provided by the load support section 32 of the rotary shelf 21 and the storage level to be provided by the load support section 103 of the fixed shelf 101 can be brought down almost to the floor; thus, the amount of storage can be increased. Therefore, the invention can be easily and suitably applied to a location where it is desired to minimize a clean space, such as a clean room 1.

In addition, since clean air A is flowing according to the downflow system within the surrounding wall body 11, the dust produced in the rotary shelf 21 or transfer means 51 can be carried by the clean air flow for quick removal. In the load storage chamber 15, therefore, storage of cassette 120 can be effected in a sufficiently clean atmosphere (degree of cleanness).

As described above, storage and retrieval of cassette 120 are effected not only through the storage load handling section 111 or retrieval load handling section 116 but also through the load passage portion 19. That is, as shown in FIGS. 1 through 3, the filled movable body 133 holding the cassette 120 by the load holding section 134 or the empty movable body 133 holding no cassette 120 is caused to travel along the conveyance path 135 by the support guide in the rail device 132 and then stopped in opposed relationship to the load passage portion 19.

Thus, actuation of the delivery means 136 after stoppage of the movable body 133 in opposed relationship to the load passage portion 19 allows delivery of the cassette 120 to and from the load holding section 134 of the movable body 133. In addition, delivery of the cassette 120 to the delivery means 136 can be effected by actuating the transfer means 51 in the manner described above. This ensures smooth storage and retrieval of the cassette 120 through the load passage portion 19.

Travel of the movable body 133 along the conveyance path 135 can be quickly and efficiently effected in the shortest distance and sufficiently close to the surrounding wall body 11 by utilizing the curved path 135a, etc., positioned outside the cut portion 16. Further, since the transfer means 131 can be disposed sufficiently close to the surrounding wall body 11, the installation space extending from the surrounding wall body 11 to the conveyance path 135 can be narrowed and easily laid out.

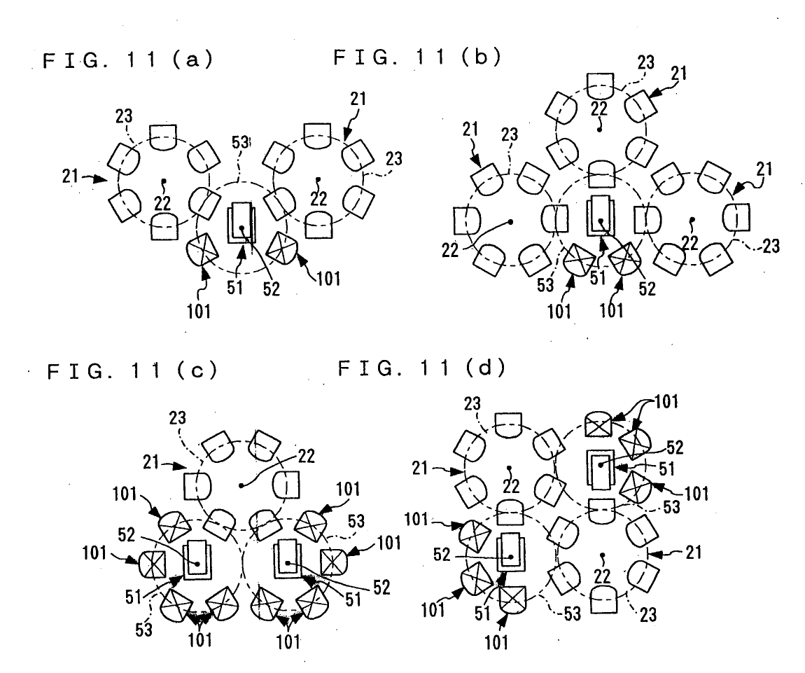

Next, second through fifth embodiments of the invention will now be described with reference to FIG. 11.

That is, FIG. 11(a) shows the second embodiment wherein the rotary shelves 21, transfer means 51 and fixed shelves 101 are associated with two rotary circular paths 23 and one transfer circular path 53.

Further, FIG. 11(b) shows the third embodiment wherein the rotary shelves 21, transfer means 51 and fixed shelves 101 are associated with three rotary circular paths 23 and one transfer circular path 53.

And FIG. 11(c) shows the fourth embodiment wherein the rotary shelf 21, transfer means 51 and fixed shelves 101 are associated with one rotary circular path 23 and two transfer circular paths 53.

Further, FIG. 11(d) shows the fifth embodiment wherein the rotary shelves 21, transfer means 51 and fixed shelves 101 are associated with two rotary circular paths 23 and two transfer circular paths 53.

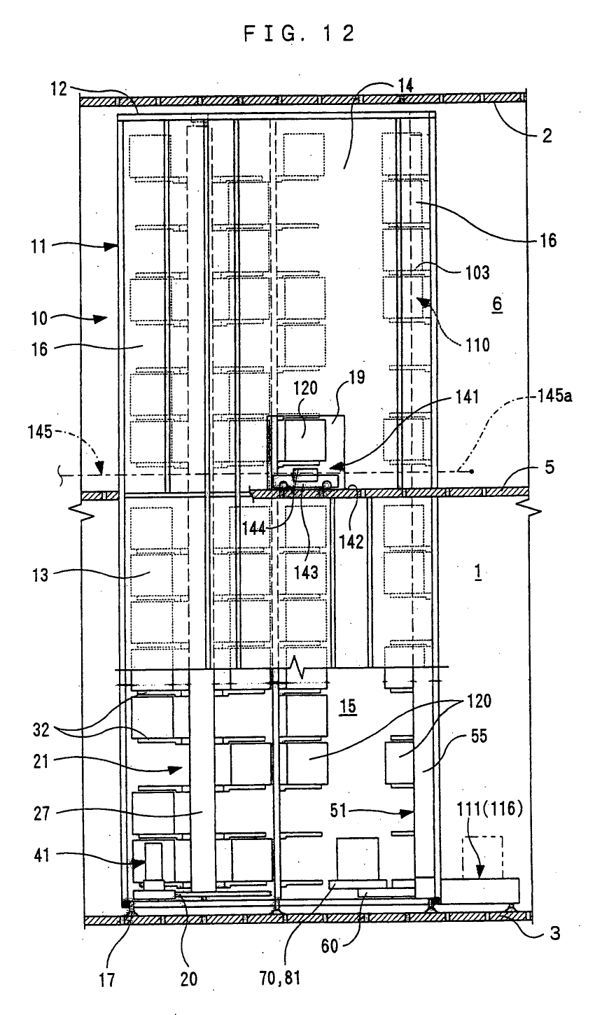

Next, a sixth embodiment of the invention will be described with reference to FIG. 12.

That is, the upper portion of the surrounding wall body 11 is positioned in the upper story clean room 6 through the upper story floor 5. Thereby, the upper outer plate 14 and cut portion 16 are positioned in the upper story clean room 6. And, a conveyance means 141 is provided which passes outside the cut portion 16 in the surrounding wall body 11.

This conveyance means 141 is composed of a rail device 142 laid on the upper story floor 5, a movable body 143 in the form of an automatic traveling carriage supported and guided by the rail device 142, a load holding section 144 installed on the upper side of the movable body 143, etc. And a conveyance path 145, which is a travel path for the movable body 143, is formed so that a curved path portion 145a is positioned outside the cut portion 16.

In this sixth embodiment, travel of the movable body 143 along the conveyance path 145 can be quickly and efficiently effected in the shortest distance and sufficiently close to the surrounding wall body 11 by utilizing the curved path portion 145a, etc., positioned outside the cut portion 16. Further, since the transfer means 141 can be disposed sufficiently close to the surrounding wall body 11, the installation space extending from the surrounding wall body 11 to the conveyance path 145 can be narrowed and easily laid out on the upper story floor 5.

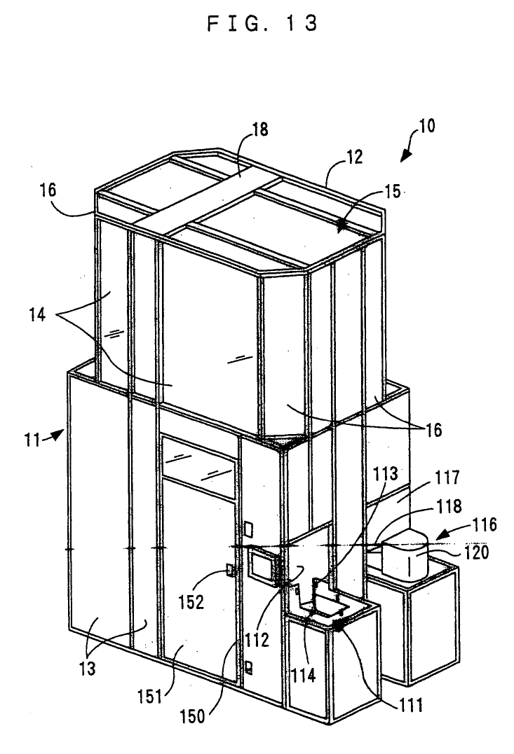

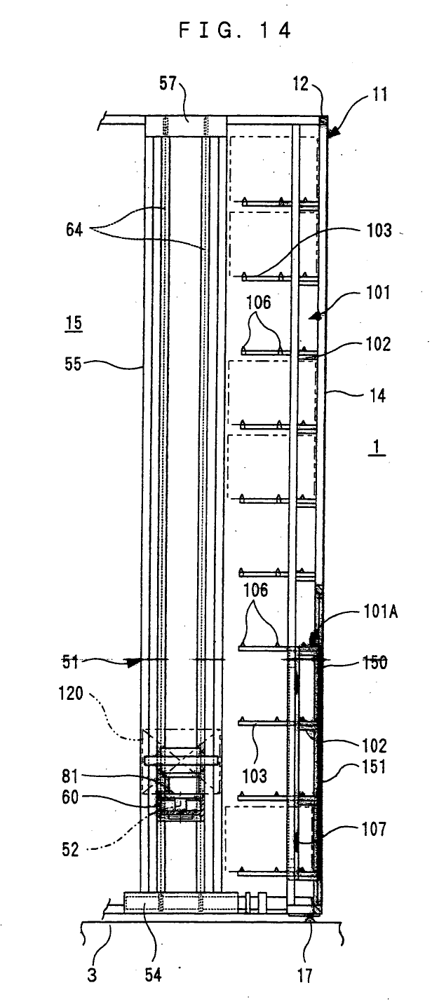

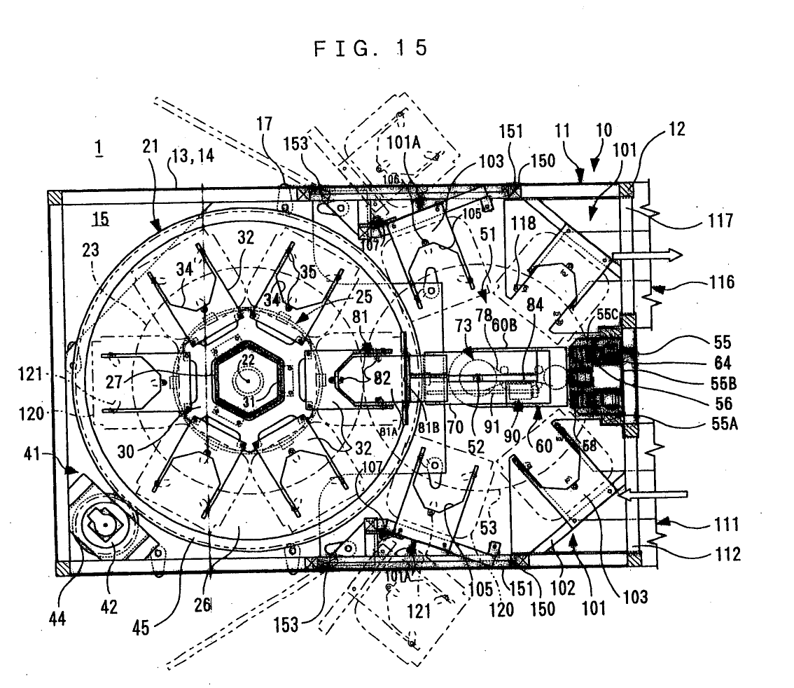

Next, a seventh embodiment of the invention will be described with reference to FIGS. 13-16.

Part of the surrounding wall body 11 is formed as an opening/closing door 151. That is, that portion of the lower outer plate 13 which is opposed to the fixed shelf 101 on the side of the rotary shelf 21 is formed as an opening 150. And one side of the opening/closing door 151 is attached to the frame body 12 through a rotary connector 153; thus, it is arranged that the opening 150 is opened/closed by rotating the opening/closing door 151 around the rotary connector 153 by operation through an operating section 152.

Installed within the opening/closing door 151 is a fixed shelf 101, which is adapted to be movable through the opening 150 left after the opening/closing door 151 has been opened. That is, in the fixed shelf 101, fixed shelves which are three steps (a single step or a plurality of steps) from bottom and opposed to the back of the opening/closing door 151 are constructed as a movable fixed shelf 101A separated from the remaining shelves of the fixed shelf 101, the flat bars 102 of the movable shelf 101A are attached at one side thereof to the frame body 12 through a rotary connector 107; thus, it is arranged that the movable fixed shelf 101A is movable through the opening 130 by rotating it around the rotary connector 107.

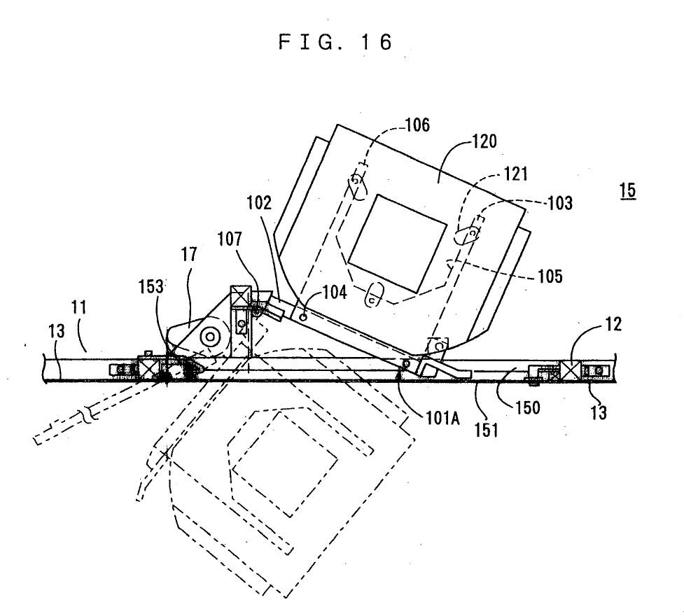

In this seventh embodiment, when the rotary shelf 21, fixed shelves 101 and 101A, transfer means 51, etc., within the surrounding wall body 11 are to be subjected to maintenance, inspection, etc., the opening/closing door 151 is rotated around the rotary connector 153 by operation through an operating section 152; thus, the opening 151 is opened as shown in phantom lines in FIG. 16. And the movable fixed shelf 101A is rotated around the rotary connector 107, and on this occasion, the movable fixed shelf 101A can be swung (moved) into the outside of the surrounding wall body 11 through the opening 150 left after the opening/closing door 151 has been opened; thus, a passage can be formed in the portion which is in the opening 150 and left by the movable fixed shelf 101A.

This allows the operator to move into and out of the surrounding wall body 11, that is, into and out of the load storage chamber 15, through the opening 150 along the passageway; thus, maintenance, inspection, etc. of the rotary shelf 21, fixed shelves 101 and 101A, transfer means 51, etc. can be effected. In addition, maintenance, inspection, etc. of the movable fixed shelf 101A may be effected outside the surrounding wall body 11.

After the intended maintenance and inspection have been effected, first the movable fixed shelf 101A is rotated around the rotary connector 107 to swing (move) into the surrounding wall body 11; thus, the movable fixed shelf 101A can be positioned in a predetermined place on the transfer circular path 53. Then, the opening/closing door 151 is rotated around the rotary connector 153 by an operation through the operating section 152; thus, the opening 150 can be closed as shown in solid lines in FIG. 16.

In the embodiments described above, the transfer means 51 is shown as being of a type in which the transfer operating section 81 thereof operates on the bottom surface of the cassette 120; however, it may be of a type in which the transfer operating section 81 is engage-wise stopped from below by a stop projecting laterally from the lateral portion or upper portion of the cassette 120.

In the embodiments described above, the transfer means 51 is shown as being of a type in which the rotary body 70 is rotatable around the transfer axis 52; however, it may be of a type in which the entire transfer means 51 including the transfer operating section 81 is rotatable around the transfer axis positioned, for example, in the post body 55.

In the embodiments described above, the fixed shelves 101 (101A) are disposed in a plurality of places on the transfer circular path 53; however, the arrangement may be of a type in which the fixed shelf 101 (101A) is disposed in a single place.

In the embodiment described above, the rotary shelf 21 is forwardly and backwardly rotatable by an angle up to a maximum of 180 degrees; however, the forward and backward rotation may exceed 180 degrees or the rotation may be allowed in one direction only.

In the embodiments described above, it is arranged that when the transfer means 51 is working with respect to the fixed shelf 101 (101A), the rotary shelf 21 is prepared in advance; however, the arrangement may be of a type in which after the working of the transfer means 51 with respect to the fixed shelf 101 (101A) has been completed, the rotary shelf 21 is prepared.

In the embodiments described above, the rotary shelf 21, transfer means 51, and fixed shelf 101 (101A) are disposed in a clean atmosphere; however, the arrangement may be of a type in which they are disposed in an atmospheric atmosphere. Further, the surrounding wall body 11 may be of a type in which it is disposed in an atmospheric room.

In the embodiments described above, the cassette 120 is shown as a load; however, it may be another article or the arrangement may be of a type in which pallets are handled.

In the embodiments described above, the storage load handling section 111 and the retrieval load handling section 116 are installed correspondingly to two fixed shelves 101 remotest from the rotary shelf 21; however, the arrangement may be of a type in which the storage load handling section 111 and the retrieval load handling section 116 are installed correspondingly to the fixed shelf 101 (101A) close to the rotary shelf 21 and two fixed shelves 101 remotest from the rotary shelf 21. In this case, two storage load handling sections 111 and two retrieval load handling sections 116 may be symmetrically disposed on both sides.

In the embodiments described above, with the overall height of the upper outer plates 14 defined as a set range, the four corners are formed as cut portions 16; however, the arrangement may be of a type in which with the overall height of the lower outer plates 13 defined as a set range, cut portions are formed or a type in which with the overall height from the upper outer plates 14 to the lower outer plates 13 defined as a set range, cut portions are formed. Further, the arrangement may be of a type in which one, two or three corners are formed as cut portions.

In the embodiments described above, the surrounding wall body 11 is formed with the load passage portion 19 for delivery of the cassette 120 to and from the conveyance means 131; however, the arrangement may be of a type in which the load passage portion 19 is not formed and delivery of the cassette 120 is not effected.

In the embodiments described above, the rotary shelf 21, transfer means 51 and fixed shelf 101 (101A) are installed within the surrounding wall body 11; however, the arrangement may be of a type in which the transfer means 51 and fixed shelf 101 (101A) are installed therewithin or a type in which other devices, implements, etc., separate from the fixed shelf 101 (101A) are installed therewithin.

1. A materials handling system including a rotary shelf rotatable around a vertically extending rotary shelf axis and a plurality of load receiving sections disposed on a rotary circular path having its center located at the rotary shelf axis, characterized in that
a rectangular box-like surrounding wall body surrounds the rotary shelf, at least one corner of the surrounding wall body being formed as a cut portion over a vertically extending set range, and a conveyance means is installed which passes outside the cut portion.

2. A materials handling system as set forth in claim 1, characterized in that
the surrounding wall body is provided with a load passage portion for delivery of loads to and from the conveyance means.

3. A materials handling system as set forth in claim 1, characterized in that
installed within the surrounding wall body, in addition to the rotary shelf, are the fixed shelf and the transfer means adapted to operate on the rotary shelf and the fixed shelf.

4. A materials handling system as set forth in claim 1, characterized in that
installed within the surrounding wall body, in addition to the rotary shelf, are the fixed shelf and the transfer means, the transfer means being disposed laterally outside the rotary shelf, a transfer operating section of the transfer means is rotatable around the transfer axis parallel with the rotary shelf axis and is adapted to operate when placed on a transfer circular path tangentially superposed on the rotary circular path, the fixed shelf being disposed on the transfer circular path.

5. A materials handling system as set forth in claim 1, characterized in that
the inside of the surrounding wall body is in a clean atmosphere.

6. A materials handling system as set forth in claim 1, characterized in that
the surrounding wall body is disposed in a clean room.

7. A materials handling system including a rotary shelf rotatable around a vertically extending rotary shelf axis and a plurality of load receiving sections disposed on a rotary circular path having its center located at the rotary shelf axis, characterized in that
a surrounding wall body surrounds the rotary shelf, and disposed within the surrounding wall body, in addition to the rotary shelf, are a fixed shelf and a transfer means adapted to operate on the fixed shelf, part of the surrounding wall body being formed as an opening/closing door, the fixed shelf being disposed in the opening/closing door, the fixed shelf being movable through an opening left after the opening/closing door has been opened.

8. A materials handling system as set forth in claim 7, characterized in that
the transfer means is adapted to operate on the fixed shelf and the rotary shelf.

9. A materials handling system as set forth in claim 7, characterized in that
the transfer means is installed laterally outside the rotary shelf, the transfer means having a transfer operating section which is rotatable around a transfer axis parallel with the rotary shelf axis and which is adapted to operate when placed on a transfer circular path tangentially superposed on the rotary circular path, and disposed on the transfer circular path is a fixed shelf which is movable through an opening left after the opening/closing door has been opened.
